(19) United States
(12) Patent Application Publication
(10) Pub. No.: US 2009/0147530 A1
(43) Pub. Date: Jun. 11, 2009

(54) LED Lamp Light Emitting Insert

(76) Inventor: Yu Lam WONG, Kowloon (HK)

Correspondence Address: TROXELL LAW OFFICE PLLC, SUITE 1404, 5205 LEESBURG PIKE, FALLS CHURCH, VA, 22041, US

(21) Appl. No.: 12/203,617

(22) Filed: Sep. 3, 2008

(30) Foreign Application Priority Data
Nov. 5, 2007 (CN) 200720170485.4

(51) Int. Cl. H01L 33/00; F21V 33/00

(52) U.S. Cl. 362/555; 362/253

(57) ABSTRACT

An LED lamp light emitting insert includes an LED lamp, a mist sprayer, and a circuit. The LED lamp and the mist sprayer are connected to the circuit through a switch. A mist spraying hole is disposed on the circumferential surface of the light emitting insert; a blind hole is disposed at an upper end of the light emitting insert and inserted with a silicone optical fiber; a star body is installed at a distal end of the silicone optical fiber. The light emitting insert is applied to a decoration such as a basket, pot, box, bunch or bouquet of fresh or artificial flowers, or a color ribbon, a church bell, an arch, a flower circle, a flower groove, a pond, and a flower car to provide light emitting and mist spraying effects The light emitting insert can be bent into different shapes to provide a natural and artistic look.

### BACKGROUND OF THE INVENTION

(a) Field of the Invention

The present invention relates to a light emitting insert, and more particularly to a light emitting diode (LED) lamp insert applied to a decoration such as a fresh or artificial flower.

(b) Description of the Related Art

At present, a basket, a pot, a box, a bunch, a bouquet, a color ribbon, a church bell, an arch, a flower circle, a flower bed, a pool and a flower car of fresh or artificial flowers is used extensively as decorations for households and public entertaining sites to achieve the effect of beautifying the environment. In addition, people use lots of fresh flowers as gifts for special occasions, and thus promoting the development of the aforementioned products.

As optical fiber is developed and introduced, optical fibers serving as a light emitting object are applied in the products of fresh or artificial flowers to improve the artistic look of the products. Since optical fibers are flexible, the optical fibers are usually tied up together into a bunch for their use, but it will affect the effect of applications.

### SUMMARY OF THE INVENTION

It is a primary objective of the present invention to overcome the shortcomings of the prior art by providing an LED lamp light emitting insert, and the light emitting insert comprises an LED lamp, a mist sprayer installed therein, and a silicone optical fiber inserted thereon, and the silicone optical fiber can be bent into various different shapes according to the stylish design of a flower decoration, and this type of light emitting insert has light emitting and mist spraying functions and overcomes the deficiency of present optical-fiber fresh or artificial flower products.

To achieve the foregoing objective, the present invention provides a technical solution of a light emitting insert comprising a light emitting insert, as well as an LED lamp, a mist sprayer and a circuit installed in the light emitting insert, wherein the LED lamp and the mist sprayer are connected to the circuit through a switch, and the light emitting insert includes a mist spraying hole disposed on a circumferential surface of the light emitting insert, and a blind hole is disposed at an upper end of the light emitting, and a silicone optical fiber is inserted into the blind hole.

The technical solution further comprises:

a star-shaped body disposed at an end of the silicone optical fiber;

a plurality of uniformly distributed mist spraying holes disposed on a circumferential surface of the light emitting insert; and

a blind hole disposed at an upper end of the light emitting insert, and having a plurality of silicone optical fibers inserted into the blind hole;

The mist sprayer includes a high-pressure water pump connected to a water tank.

The LED lamp can emits lights of seven colors.

The light emitting insert can be installed in a basket, a pot, a box, a bunch, a bouquet, a color ribbon, or a flower car.

The light emitting insert can be installed in a bamboo garden, and each bamboo comes with one light emitting insert.

Another technical solution of the present invention is to provide a light emitting insert having a light emitting insert, and the light emitting insert installs an LED lamp and a circuit therein, and the LED lamp is connected to the circuit through a switch, and a blind hole is disposed at an upper end of the light emitting insert, and a silicone optical fiber is inserted into the blind hole, and a transparent crystal is inserted at the top of the silicone optical fiber.

The technical solution further comprises the following:

The transparent crystal includes a text, a figure, a number, a combination of text and figure, a combination of number and text, a combination of number and figure, or a combination of text, figure and number, made of the transparent crystal.

The transparent crystal includes a star body made of the transparent crystal.

The transparent crystal includes a trademark logo made of the transparent crystal.

The text, figure, number, combination of text and figure, combination of number and text, combination of number and figure, or combination of text, figure and number made of the transparent crystal is installed at the bottom of a glass tabletop and inserted into an end of the silicone optical fiber, and another end of the silicone optical fiber is connected to an LED lamp, and the LED lamp is connected to an electric power.

The text, figure, number, combination of text and figure, combination of number and text, combination of number and figure, or combination of text, figure and number made of the transparent crystal is installed at the backside of a glass wall and inserted into an end of the silicone optical fiber, and another end of the silicone optical fiber is connected to an LED lamp, and the LED lamp is connected to an electric power.

The text, figure, number, combination of text and figure, combination of number and text, combination of number and figure, or combination of text, figure and number made of the transparent crystal is installed at backside of a glass floor and inserted into an end of the silicone optical fiber, and another end of the silicone optical fiber is connected to an LED lamp, and the LED lamp is connected to an electric power.

The text, figure, number, combination of text and figure, combination of number and text, combination of number and figure, or combination of text, figure and number made of the transparent crystal is installed in a flower box and inserted into an end of the silicone optical fiber, and another end of the silicone optical fiber is connected to an LED lamp, and the LED lamp is connected to an electric power.

The text, figure, number, combination of text and figure, combination of number and text, combination of number and figure, or combination of text, figure and number made of the transparent crystal is installed at a billboard and inserted into an end of the silicone optical fiber, and another end of the silicone optical fiber is connected to an LED lamp, and the LED lamp is connected to an electric power.

The present invention has the following advantages. The LED lamp light emitting insert is manufactured to be used together with a fresh flower product or an artificial flower product, and the silicone optical fiber is waterproof and bendable into various different shapes. A text, figure or number made of a transparent crystal can be inserted to the top of the silicone optical fiber to achieve a personalized or advertising effect by forming the crystal text and figure according to a shop name, a sign or a trademark. The present invention also provides light emitting and mist spraying effects to improve the natural feeling effect, enhance the artistic look, and achieve a simple structure, a low cost, a convenient use, and an excellent effect.

### BRIEF DESCRIPTION OF THE DRAWINGS

FIG. 1 is a schematic view of an overall structure of the present invention;

FIG. 2 is a schematic view of applying the present invention to a basket of fresh flowers in accordance with the present invention;

FIG. 3 is a schematic view of a basket of FIG. 2;

FIG. 4 is a schematic view of an application used at the bottom of a glass tabletop in accordance with the present invention;

FIG. 5 is a schematic view of an application used at a flower box (or a gift box) in accordance with the present invention;

FIG. 6 is a schematic view of an application used at the backside of a glass wall in accordance with the present invention;

FIG. 7 is a schematic view of an application used at the bottom of a glass floor in accordance with the present invention;

FIG. 8 is a schematic view of an application of a star body made of a transparent crystal in accordance with the present invention; and

FIGS. 9 and 10 are schematic views of applications of a Chrysler logo and a Benz logo made of a transparent crystal in accordance with the present invention respectively

In the figures, the following numerals are used for indicating their respective elements: 1 water tank, 2 water pipe, 3 high-pressure water pump, 4 light emitting insert, 41 blind hole, 42 mist spraying hole, 5 LED lamp, 6 silicone optical fiber, 61 star-shaped body, 7 circuit, 8 press-button switch, 9 basket, 10 fresh flower, 11 crystal number, 12 glass tabletop, 13 table leg, 14 crystal star, 15 crystal Chrysler logo, 16 crystal Benz logo, 17 flower box, 18 glass wall, 19 glass floor, and 20 crystal text.

### DETAILED DESCRIPTION OF THE PREFERRED EMBODIMENTS

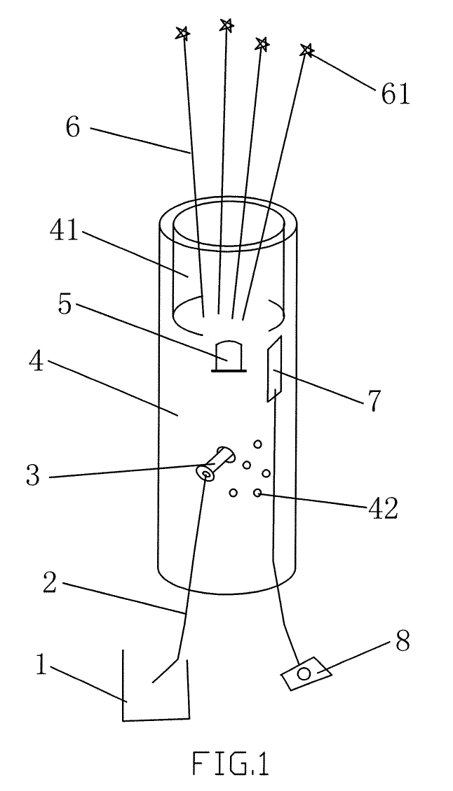

With reference to FIG. 1 for the illustration of the present invention, an LED lamp light emitting insert of the invention provides light emitting and mist spraying functions and comprises a light emitting insert 4, an LED lamp 5, a high-pressure water pump 3, a water tank 1, a circuit 7, and a press-button switch 8, wherein the light emitting insert 4 includes a blind hole 41 disposed at an upper end of the light emitting insert 4, and a plurality of uniformly distributed mist spraying holes 42 disposed at a circumferential surface of the light emitting insert 4. The LED lamp 5, the high-pressure water pump 3 and the circuit 7 are installed in the light emitting insert 4, wherein the high-pressure water pump 3 is connected to the water tank 1 through a water pipe 2, and the press-button switch 8 is connected to the high-pressure water pump 3 and the LED lamp 5 through the circuit 7, and a plurality of silicone optical fibers 6 are inserted into the blind hole 41 of the light emitting insert 4. The silicone optical fiber 6 is made by mixing PPC and silicone, and thus is flexible, and a star-shaped body (such as a star) 61 is connected to the top of the silicone optical fiber 6.

The operating principle of the invention is described as follows. The press-button switch is pushed to turn on the LED lamp to emit color lights. The light lights up the silicone optical fiber and the star-shaped body, and the quantity of silicone optical fibers is determined by the quantity of flowers, and the shape can be bent or the length can be shortened according to a desired flower arrangement. When the LED lamp is turned on, the high-pressure water pump is operated to spray mists from the light emitting insert. The LED lamp and the high-pressure water pump can be operated at the same time, or not at the same time, or only one is operating while the other is not.

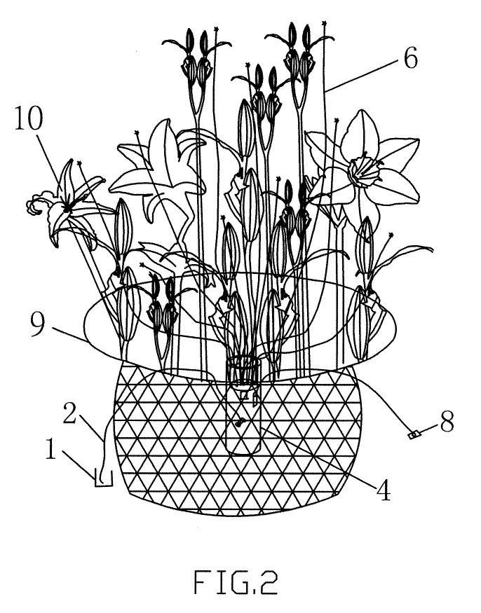

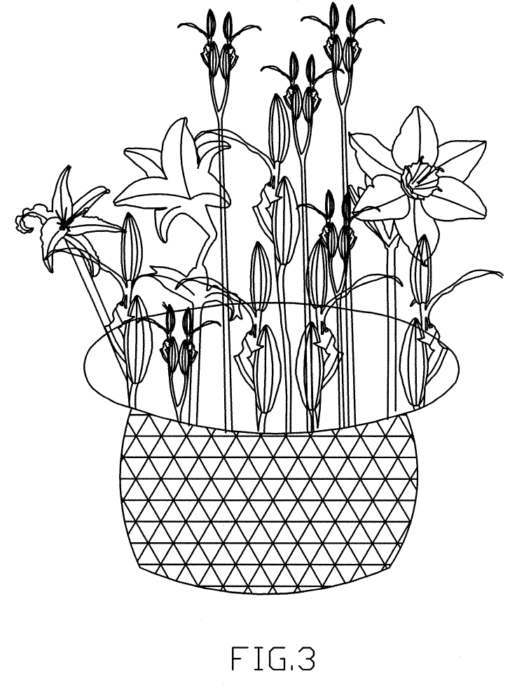

With reference to FIG. 2 for the first preferred embodiment, a basket containing mud is prepared, and fresh flowers are inserted into the mud, and the LED lamp light emitting insert is inserted in the middle of the mud. The insert includes a silicone optical fiber inserted thereon, and the shape, quantity and length of the silicone optical fiber depend on the desired effect. Mists are sprayed to maintain the fresh flower for a longer time.

In addition to the basket, the LED lamp light emitting insert can be used for any product that requires an LED lamp optical fiber and a mist spraying effect.

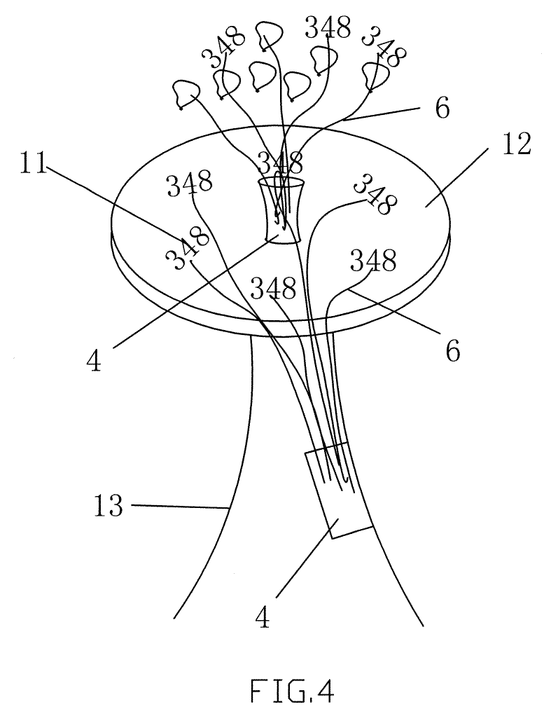

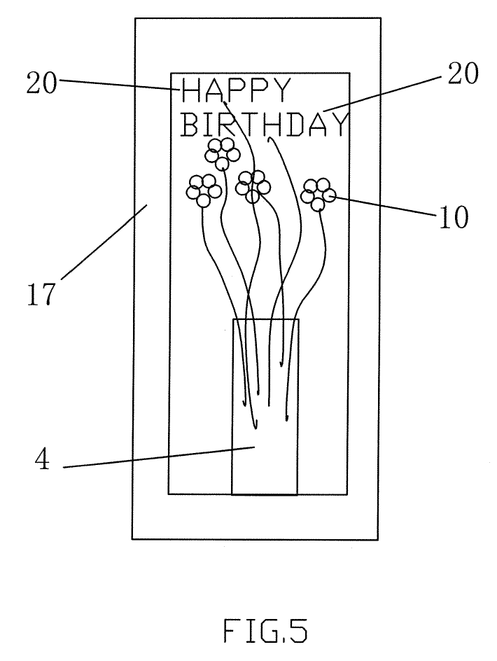

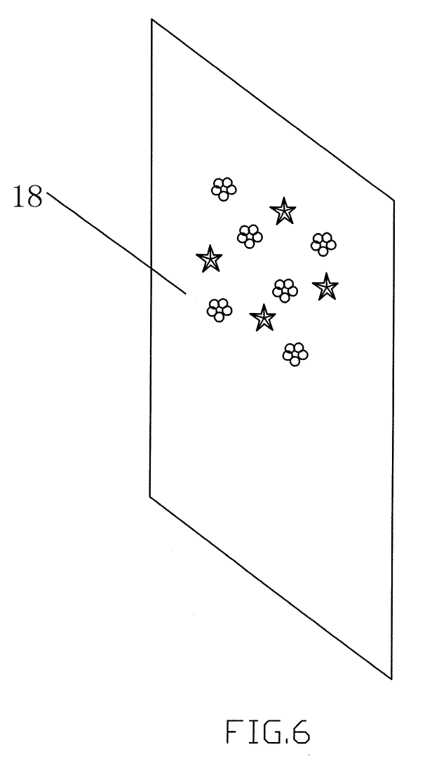

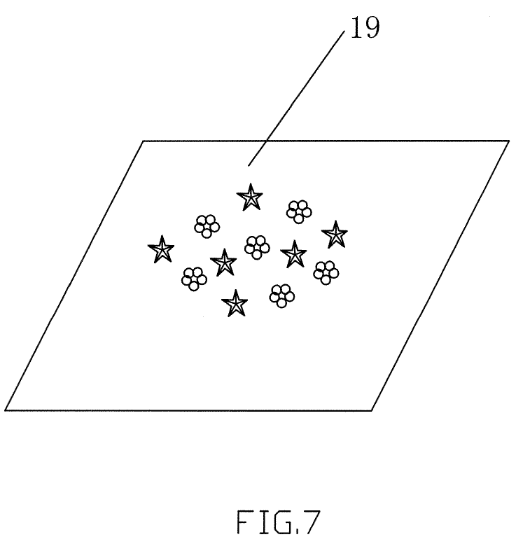

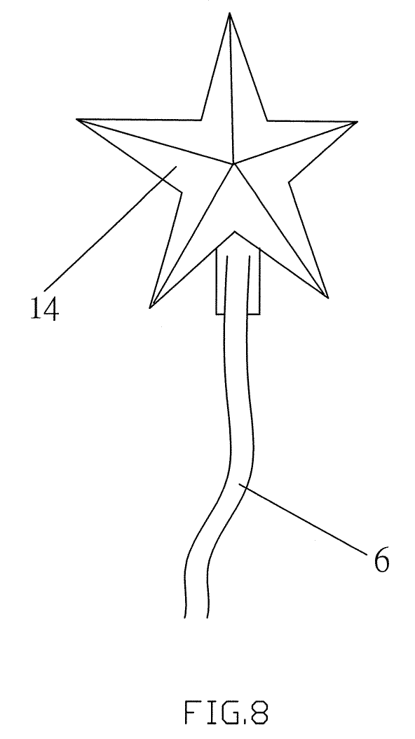

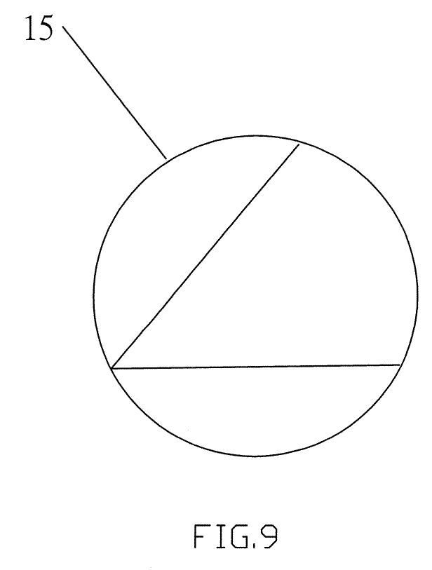

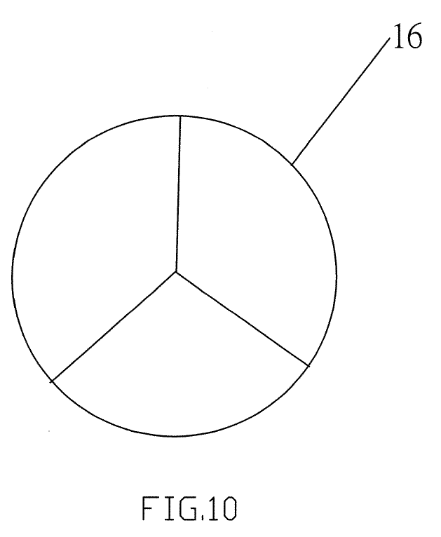

The characteristics of another structure of the LED lamp light emitting insert reside on that a transparent crystal is inserted at the top of the silicone optical fiber 6 and an LED lamp is installed at the bottom of the silicone optical fiber 6, wherein the transparent crystal can be made into a number 11 (as shown in FIG. 4), a FIG. 14, 15, 16 (as shown in FIGS. 8 to 10), a text 20 (as shown in FIG. 5), a trademark or an advertising, or a combination of the above, and the figures include different shapes of animals.

The LED lamp made of the silicone optical fiber and the transparent crystal can be used in a tabletop, a flower box, a gift box, a glass wall, a glass floor, an automobile sign, a birthday party, a ballroom, a night club, a bar, a flower pool, a flower column, a roadside, an exhibition, a billboard, a color strip, a color ribbon, a bag, a hat, a cloth, a pair of tennis shoes, a shop sign, and a Christmas tree.

I claim,

1. A light emitting diode (LED) lamp light emitting insert, characterized in that said light emitting insert comprises a light emitting insert, and an LED lamp, a mist sprayer and a circuit installed in said light emitting insert, and said LED lamp and said mist sprayer are coupled to said circuit through a switch, and a mist spraying hole is disposed on a circumferential surface of said light emitting insert, and a blind hole is disposed at an upper end of said light emitting insert, and a silicone optical fiber is inserted into said blind hole.

2. The LED lamp light emitting insert of claim 1, wherein said silicone optical fiber has a star-shaped body disposed at an end of said silicone optical fiber.

3. The LED lamp light emitting insert of claim 1, wherein said light emitting insert includes a plurality of uniformly distributed mist spraying holes disposed on a circumferential surface of said light emitting insert.

4. The LED lamp light emitting insert of claim 1, wherein said blind hole at an upper end of said light emitting insert is inserted with a plurality of silicone optical fibers.

5. The LED lamp light emitting insert of claim 1, wherein said mist sprayer comprises a high-pressure water pump connected to a water tank.

6. The LED lamp light emitting insert of claim 1, wherein said LED lamp emits lights of seven colors.

7. The LED lamp light emitting insert of claim 1, wherein said light emitting insert is installed in a basket, a pot, a box, a bunch, a bouquet, a color ribbon, or a flower car.

8. The LED lamp light emitting insert of claim 1, wherein said light emitting insert is installed in a bamboo garden, and each bamboo is installed with one light emitting insert.

9. An LED lamp light emitting insert, characterized in that said light emitting insert comprises a light emitting insert, and said light emitting insert installs an LED lamp and a circuit, and said LED lamp is coupled to said circuit through a switch, and a blind hole is disposed at an upper end of said light emitting insert, and a silicone optical fiber is inserted into said blind hole, and a transparent crystal is inserted into the top of said silicone optical fiber.

10. The LED lamp light emitting insert of claim 9, wherein said transparent crystal includes a text, a figure, a number, a combination of text and figure, a combination of number and text, a combination of number and figure, a combination of text, figure and number made of said transparent crystal.

11. The LED lamp light emitting insert of claim 10, wherein said transparent crystal includes a star made of said transparent crystal.

12. The LED lamp light emitting insert of claim 10, wherein said transparent crystal includes a trademark logo made of said transparent crystal.

13. The LED lamp light emitting insert of claim 10, wherein said text, figure, number, combination of text and figure, combination of number and text, combination of number and figure, or combination of text, figure and number made of said transparent crystal is installed at the bottom of a glass tabletop and inserted into an end of said silicone optical fiber, and another end of said silicone optical fiber is coupled to said LED lamp, and said LED lamp is coupled to an electric power.

14. The LED lamp light emitting insert of claim 10, wherein said text, figure, number, combination of text and figure, combination of number and text, combination of number and figure, or combination of text, figure and number made of said transparent crystal is installed at the backside of a glass wall, and inserted into an end of said silicone optical fiber, and another end of said silicone optical fiber is coupled to said LED lamp, and said LED lamp is coupled to an electric power.

15. The LED lamp light emitting insert of claim 10, wherein said text, figure, number, combination of text and figure, combination of number and text, combination of number and figure, or combination of text, figure and number made of said transparent crystal is installed at the backside of a glass floor, and silicone optical fiber inserted into an end of said silicone optical fiber, and another end of said silicone optical fiber is coupled to said LED lamp, and said LED lamp is coupled to an electric power.

16. The LED lamp light emitting insert of claim 10, wherein said text, figure, number, combination of text and figure, combination of number and text, combination of number and figure, or combination of text, figure and number made of said transparent crystal is installed at a box and inserted into an end of said silicone optical fiber, and another end of said silicone optical fiber is coupled to said LED lamp, and said LED lamp is coupled to an electric power.

17. The LED lamp light emitting insert of claim 10, wherein said text, figure, number, combination of text and figure, combination of number and text, combination of number and figure, or combination of text, figure and number made of said transparent crystal is installed on a billboard and inserted into an end of said silicone optical fiber, and another end of said silicone optical fiber is coupled to said LED lamp, and said LED lamp is coupled to an electric power.

18. The LED lamp light emitting insert of claim 9, wherein said transparent crystal includes a star made of said transparent crystal.

19. The LED lamp light emitting insert of claim 9, wherein said transparent crystal includes a trademark logo made of said transparent crystal.
